(19) United States
(12) Patent Application Publication
(10) Pub. No.: US 2024/0213366 A1
(43) Pub. Date: Jun. 27, 2024

(54) VERTICAL TRANSISTORS AND METHOD FOR PRODUCING THE SAME

(71) Applicant: Robert Bosch GmbH, Stuttgart (DE)

(72) Inventors: Christian Huber, Ludwigsburg (DE); Jens Baringhaus, Sindelfingen (DE); Roland Puesche, Rommelsbach (DE)

(21) Appl. No.: 18/557,252

(22) PCT Filed: Apr. 20, 2022
(86) PCT No.: PCT/EP2022/060319

§ 371 Date: Oct. 25, 2023

(30) Foreign Application Priority Data
Apr. 29, 2021 (DE) 10 2021 204 293.7

(51) Int. Cl. H01L 29/78; H01L 29/20; H01L 29/417; H01L 29/423

(52) U.S. Cl. CPC H01L 29/7813; H01L 29/2003; H01L 29/41741; H01L 29/4236; H01L 29/7811

(57) ABSTRACT

A vertical transistor with an outer region and a membrane region. At least a portion of a semiconductor substrate is arranged in the outer region. The semiconductor substrate is structured in such a way that a rear trench is arranged in the membrane region. The rear trench is free of semiconductor substrate. A masking layer is arranged in the outer region and/or in the membrane region. A layer stack is arranged in the membrane region, wherein the layer stack includes at least one drift layer, at least one component-defining layer system, and at least one control terminal, preferably a gate electrode. The masking layer is configured such that the region on the masking layer is substantially free of the layer stack so that the lateral extension of the layer stack is adjusted by means of the masking layer.

### BACKGROUND INFORMATION

Transistors on the basis of gallium nitride (GaN) offer the possibility of realizing components with lower on-resistances with simultaneously higher breakdown voltages than comparable components on the basis of silicon or silicon carbide.

GaN transistors are used primarily in so-called high-electron mobility transistors (HEMTs), in which the current flow takes place laterally on the substrate upper side through a two-dimensional electron gas forming the transistor channel. Such lateral components can be produced by heteroepitaxy of the functional GaN layers on silicon wafers. However, for a high breakdown voltage with a small on-resistance per unit area, vertical components in which the current flows from the substrate front side to the substrate rear side are more advantageous in terms of both the overall size and the electrical field distribution inside the component. Such a component cannot be directly represented by means of heteroepitaxial GaN layers on silicon (Si) since insulating intermediate layers (a so-called buffer) are required for the adjustment of the lattice mismatch between GaN and Si and for the reduction of the substrate curvature.

The buffer itself is mechanically stressed in such a way that it just compensates for the stress of the GaN layers at room temperature. However, since the buffer is an insulator, the buffer prevents the current flow from the substrate front side to the substrate rear side.

Native GaN substrates are also available, on which the required additional epitaxial GaN layers of the component can be grown without the need for an insulating buffer. However, such GaN substrates are small (typically 50 mm diameter) and expensive.

In order to reduce the transistor price per surface element, it may be advantageous to utilize the available heteroepitaxial GaN layers on large silicon substrates. Vertical components (trench MOSFET, pn diode) are conventional for this purpose, in which the silicon substrate and the insulating buffer under the component are selectively removed, whereby a rear trench is formed in order to thus be able to directly contact the rear side of the drift zone of the component. FIG. 1A shows the principal structure of such a component with insulating buffer and rear trench (here on the basis of a trench MOSFET). Hereinafter, the rear trench may also be referred to as a rear cavity or rear aperture.

As illustrated in FIG. 1A, the following III-V nitride semiconductor layers (GaN with the exception of the buffer) have grown epitaxially on the silicon substrate 61 or, in general, the carrier substrate: the insulating buffer 13, a high-doped contact semiconductor layer having n-conductivity 14, the low-doped, n-conductive drift layer 15, a p-conductive body layer 16 and a high-doped n-conductive source contact layer 17.

Source contact layer 17 and body layer 16 are penetrated by a trench, the side walls and the bottom of which are separated from the gate electrode 21 by a gate dielectric 22. Source contact layer 17 and body layer 16 are contacted by a source electrode 41, which is separated from the gate electrode 21 by an insulation layer 31. On the rear side, the silicon substrate 61 and the buffer 13 are removed through a rear trench 51, which terminates in the high-doped contact semiconductor layer having n-conductivity 14. The latter is contacted by a rear drain electrode 52. In operation, a conductive channel is formed in the body layer 16 by applying a gate voltage to the gate electrode 21, through which channel a current flow from the source electrode 41 to the drain electrode 52 is enabled.

In FIG. 1A, a transistor with three cells, i.e., three repeating structures, is illustrated for simplification. In a real transistor, many such cells are typically present and thus effectively connected in parallel. Typical active surfaces are in the range of some square millimeters; the remaining GaN layers have a thickness of some micrometers. The drain electrode 52 can consist of several metallic layers.

FIG. 1B shows a simplified form of representation of the component of FIG. 1A, which is also used in the following figures. In the representation of FIG. 1B, the semiconductor layers and dielectrics as well as their structuring above the drift layer 15 are combined to form a component-defining layer system 18, wherein a terminal for the source electrode 41 and a terminal for the gate electrode 21 being shown on the upper side thereof. The component-defining layer system 18 can comprise, for example in the lateral direction, a multitude of repeating transistor cells.

However, in the case of full-surface epitaxy, the maximum GaN thickness is limited and thus the maximum breakdown voltage is limited. In addition, defect density in the growth of GaN on silicon substrates is high in comparison to growth on a native GaN substrate.

In the related art, suitable, laterally structured masking layers (e.g., SiO₂ or SiN) on a semiconductor substrate (e.g., Si, SiC, GaN) or on an epitaxial layer (e.g., a III-V semiconductor) can be used to realize site-selective growth of III-V semiconductors. For example, no epitaxial growth of GaN takes place on a SiO₂ layer. By means of a local removal of SiO₂ by common methods of micro structuring, a template for site-selective growth can thus be created (also referred to as selective-area growth (SAG), or as epitaxial lateral overgrowth (ELOG) for a more or less pronounced lateral overgrowth of the masking layer depending on epitaxial layer growth parameters). As a result, GaN can grow on predefined islands. The maximum achievable GaN epitaxy layer thickness for heteroepitaxy on silicon wafers is currently limited to a few μm since high layer stress builds as a result of the highly different thermal expansion coefficients of GaN and Si. Stress relaxation within the layer leads to defects and thus to reduction of the crystal quality, which in turn adversely affects the performance of electronic power components. In the case of SAG, the layer stress at the edge of the islands can be reduced if growth on Si takes place on a smaller surface to begin with.

Tanaka et al., “Si Complies with GaN to Overcome Thermal Mismatches for the Heteroepitaxy of Thick GaN on Si,” Advanced Materials (2017), describes GaN layers having a thickness of 19 μm and a low density of screw dislocations by means of SAG. Also described is that so-called pseudo-vertical GaN transistors can be realized, in which the current flow occurs vertically through a drift zone, but the drain current is discharged, in contrast to a true vertical component, by means of a laterally offset electrode on the substrate front side. The disclosed transistor is thus clearly a pseudo-vertical GaN transistor on the basis of a SAG GaN layer. The entire drain current is in this case tapped via the laterally offset electrode on the front side. This limits the minimum achievable on-resistance and maximum, reasonably usable transistor size.

It is described in U.S. Pat. No. 7,679,104 B2 that GaN Schottky diodes and power MOSFETs can be realized by means of SAG, wherein the gate electrode is formed next to or laterally between GaN zones, as a result of which the transistor price per surface element is relatively high. It is furthermore disclosed that vertical Schottky diodes can be realized by locally removing the silicon substrate and the buffer under each grown island so that a via is located under each island. However, as a result of this configuration, the drain contact resistance of the component is high since only a small surface defined by the surface of the rear cavity under each island is available for forming the drain contact.

### SUMMARY

A vertical transistor having features according to the present invention can clearly be a vertical GaN component, based on a foreign substrate made of a semiconductor material other than GaN, a heteroepitaxial GaN layer or a layer system of which at least a portion has been grown site-selectively as a layer stack (also referred to as an island), with at least one transistor cell per island, a rear cavity (also referred to as a rear trench or recess) in the foreign substrate under at least a portion of at least one island, and at least one electrical contact to the front side and rear side of the GaN layer. The control terminal of the transistor is formed entirely on the island in this case.

The vertical transistor according to the present invention may have the advantage over the related art that thicker epitaxy layers with lower offset density can be realized than in vertical GaN components of the related art, whereby higher breakdown voltages and lower leakage currents are enabled. A true vertical transistor architecture is enabled, whereby the drain contact resistance and thus the on-resistance can be reduced. By means of SAG, higher growth rates are possible, whereby production costs or the transistor price per surface element can be reduced. Technically lower buffer requirements are made possible in comparison to full-surface growth, whereby production costs can be reduced. The surface utilization of the substrate becomes more efficient, whereby the transistor price per surface element can be reduced. Mechanical stress in the islands can be reduced, whereby wafer bow and process risks can be reduced.

Developments of the aspects and advantageous embodiments of the vertical transistor of the present invention are disclosed herein.

### BRIEF DESCRIPTION OF THE DRAWINGS

Exemplary embodiments of the present invention are shown in the figures and are explained in more detail below.

FIG. 1A and FIG. 1B show schematic representations of a vertical transistor of the related art.

FIG. 2A to FIG. 7E show schematic representations of a vertical transistor according to various aspects of the present invention.

### DETAILED DESCRIPTION OF EXAMPLE EMBODIMENTS

In the following description, reference is made to the figures, which form part of this description and in which, for illustration purposes, specific exemplary embodiments are shown in which the present invention can be performed. It is understood that other exemplary embodiments may be used and structural or logical changes may be made without departing from the scope of the present invention. It is understood that the features of the various exemplary embodiments described herein may be combined with one another unless specifically stated otherwise. The following extensive description is therefore not to be understood in a limiting sense. In the figures, identical or similar elements are provided with identical reference signs, to the extent that this is expedient.

In the description below, various aspects and embodiments are described using the example of a trench MOSFET. However, it is understood that the possibility of providing such conductive access to the rear side of a drift zone by means of a rear trench is not limited to a trench MOSFET so that, in principle, any controlled vertical power semiconductor components can be produced by this technology, such as vertical-diffusion MOSFETS (VDMOS), current-aperture vertical electron transistors (CAVETs), vGroove vertical high electron mobility transistors (vHEMTs) or fin field effect transistors (FinFETs).

Within the framework of this description, the term “vertical transistor” is used synonymously with the term “controllable vertical semiconductor component” and describes a vertical semiconductor component that has a control terminal, e.g., a gate electrode, for controlling the current conductivity of the vertical semiconductor component.

### DETAILED DESCRIPTION OF EXAMPLE EMBODIMENTS

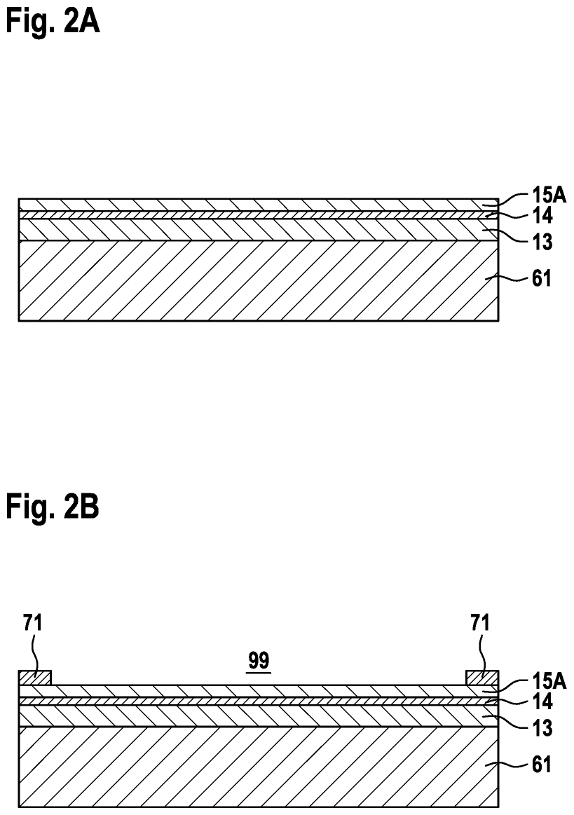

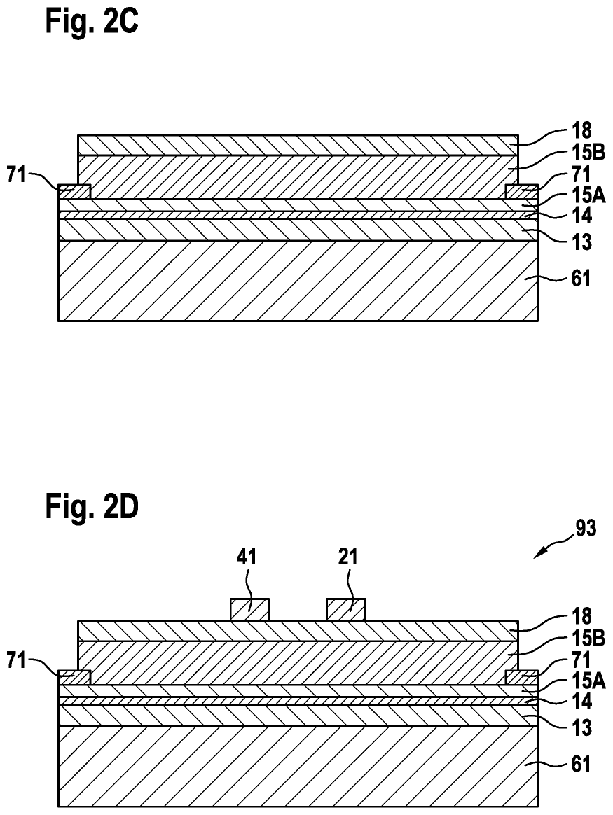

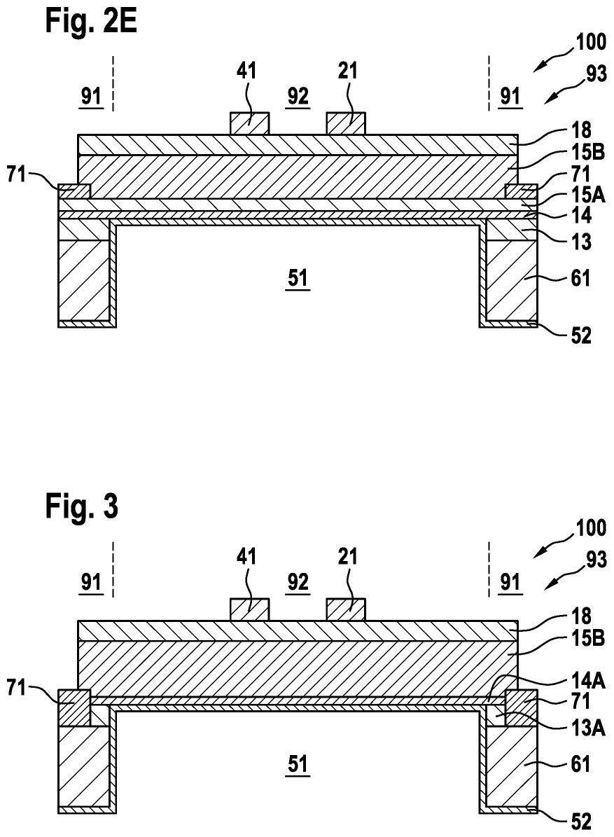

FIG. 2A to FIG. 2E illustrate, in schematic cross-sectional views, a production method of a vertical transistor 100 according to various embodiments of the present invention.

In FIG. 2A, a semiconductor substrate 61, which is not gallium nitride (GaN), is provided. The semiconductor substrate 61 comprises or is formed from silicon, for example. A full-surface epitaxial adaptation layer 13 (also referred to as buffer 13) may be applied onto the semiconductor substrate 61. The buffer 13 may comprise a layer system made of aluminum nitride (AlN), aluminum gallium nitride (AlGaN), and GaN layers. A high-doped drain layer 14 and a full-surface first drift layer 15A can be applied onto the buffer 13. The first drift layer 15A can have a thickness in the range of approx. 200 nm to approx. 3 μm.

FIG. 2B illustrates that a masking layer 71 for SAG is applied in structured form onto the surface of the drift layer 15A. For example, the masking layer 71 may comprise or be formed from SiO₂ or SiN. The masking layer 71 can be structured in such a way that the first drift layer 15A is exposed in at least one region 99. At least one vertical transistor 100 or a transistor cell of the vertical transistor 100 is to be formed in the exposed region 99. The lateral extension of the exposed region 99 can be in a range of approx. 400 μm to approx. 5 mm.

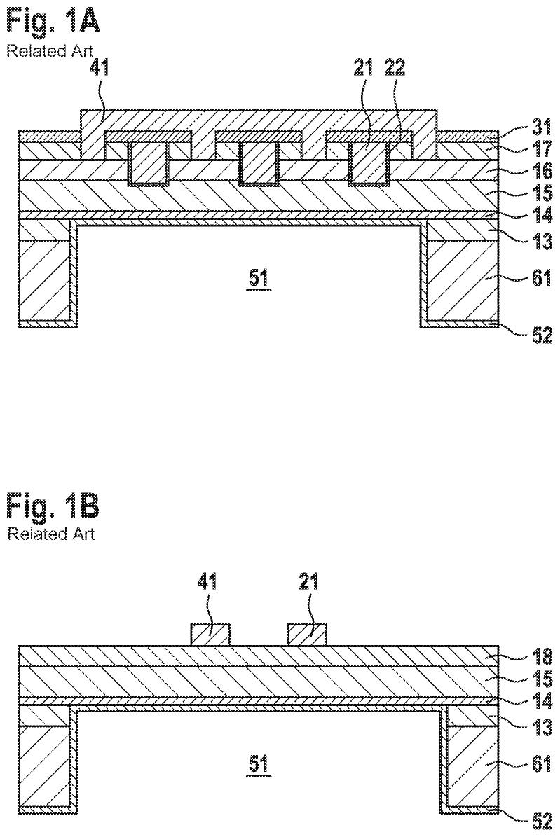

FIG. 2C illustrates that a second drift layer 15B and the component-defining layer system 18 defined in the context of FIG. 1B are deposited by means of SAG onto the first drift layer 15A in the exposed region 99 and subsequently structured by means of common methods of microprocessing.

Due to the SAG, these layers 15B, 18 grow on the first drift layer 15A only in the exposed region 99 defined by the masking layer 71. During the growth of the layers 15B, 18, a minor lateral overgrowth of the masking layer 71 can occur, as illustrated in FIG. 2C. The masking layer 71 clearly defines a laterally isolated layer stack 93 (also referred to as island 93).

FIG. 2D illustrates that at least one source electrode 41 and at least one gate electrode 21 are formed on the island 93. In a manner specific to the application, a multitude of source electrodes 41 and/or a multitude of gate electrodes 21 may be formed on a common island 93 and in a common rear trench 51.

FIG. 2E illustrates that the semiconductor substrate 61 and buffer 13 have been removed or reduced underneath the island 93 on the rear side, whereby a rear trench 51 (also referred to as recess 51) is formed. The recess 51 may also extend into the drain layer 14. For rear contacting of the vertical transistor 100, a drain contact 52 may be formed on or above the exposed layers of the rear trench 51 on the rear side. Laterally, the recess 51 may comprise the entire or substantially the entire region underneath the island 93. The recess 51 may have the same or substantially the same surface area as the exposed region 99. As a result, a membrane region 92 as the region defined laterally by the recess 51, and an outer region 91 can be defined.

The first drift layer 15A and the second drift layer 15B together can form the (entire) drift layer of the vertical transistor 100 and can specify the breakdown voltage of the vertical transistor 100.

For the performance of the vertical transistor 100, the division into first drift layer 15A and second drift layer 15B is of secondary importance. For example, (in a limit case), the first drift layer 15A may have a thickness of 0 nm, may, for example, not be present or may be an atomic layer. In this case, the entire drift layer 15A+15B can be formed by means of SAG. Alternatively, the second drift layer 15B may have a thickness of 0 nm, may, for example, not be present or may be an atomic layer. In this case, the component-defining layer system 18 can be formed by means of SAG first. As a result, a high crystal quality of the grown GaN layers can be realized by means of SAG. Alternatively, thick drift layers 15A, 15B may be formed, whereby a vertical transistor with a high breakdown voltage can be realized.

By correspondingly designing the rear recess 51 under the entire or substantially under the entire island 93, the current can flow completely perpendicularly through the vertical transistor 100. As a result, a large surface can be provided for contact between the drain layer 14 and the drain contact 52, whereby the on-resistance of the vertical transistor 100 can be reduced.

In various embodiments, a multitude of transistor cells can be arranged on a common island 93 or realized in the component-defining layer system 18. As a result, a multitude of gate electrodes 21 (also referred to as control terminal) can be arranged on a common island 93. This enables more efficient surface utilization in comparison to the related art and thus a lower transistor price per surface element.

In other words, the vertical transistor 100 can have an outer region 91 and a membrane region 92. At least a portion of the semiconductor substrate 61 is arranged in the outer region 91. The semiconductor substrate 61 is structured in such a way that a rear trench 51 is arranged in the membrane region 92. The rear trench 51 is free of semiconductor substrate 61. A layer stack 93 (also referred to as island 93) is arranged in the membrane region 92, wherein the layer stack 93 comprises at least one drift layer 15A, 15B, 15, at least one component-defining layer system 18 and at least one control terminal 21, preferably a gate electrode 21. The masking layer 71 is configured such that the region on the masking layer 71 is substantially free of the layer stack so that the lateral extension of the layer stack 93 is adjusted by means of the masking layer 71.

FIG. 3 shows an alternative embodiment of the vertical transistor 100 illustrated in FIG. 2E. In the embodiment illustrated in FIG. 3, the masking layer 71 can be formed directly on the semiconductor substrate 61 and all subsequent epitaxial layers (e.g., buffer 13A, drain layer 14A, drift layer 15B, component-defining layer system 18) can be formed by means of SAG. This makes it possible that the stress relaxation of the epitaxial layers 13A, 14A, 15B, 18 by means of SAG takes place for all epitaxial layers 13A, 14A, 15B, 18 and that a high crystal quality can thereby be achieved. Analogously, the buffer 13 can be grown over the entire surface and the SAG can start at or within the drain layer 14A.

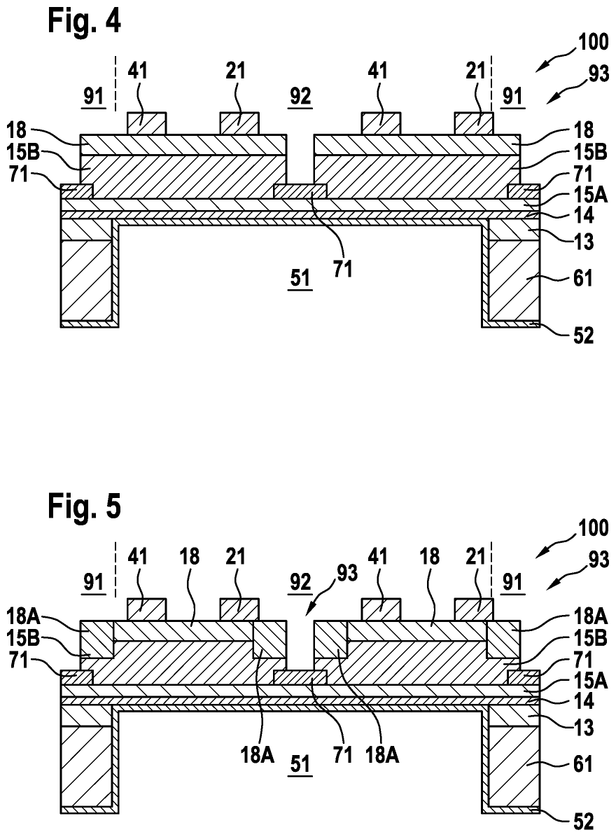

FIG. 4 shows an alternative embodiment of the vertical transistor 100 illustrated in FIG. 2E. In the embodiment illustrated in FIG. 4, two or more islands 93 with corresponding component-defining layer systems 18 and front-side electrodes (for example, source electrode 41 and gate electrode 21) may be arranged above a common recess 51 for the islands 93. Each of the islands 93 can have one or more transistor cells and one or more front-side electrodes 41, 21 in each case. This makes it possible that, with the same component surface, more island edge region, within which layer stress can be reduced, is available as a result of the multitude of islands 93. In other words, it may be simpler in this embodiment to form thick GaN islands 93 of high crystal quality when the surface area per island 93 is small. In this case, fewer defects are produced during growth, which can lead to a higher yield/higher proportion of good parts. In order to realize a vertical transistor 100 with a low on-resistance for high currents despite a small island surface area, several islands 93 can be operated electrically in parallel in the vertical transistor 100. In this case, the rear recess 51 extends over several islands 93. As a result, the entire surface for the contact between the drain layer 14 and the drain contact metal 52 is large and the on-resistance of the vertical transistor 100 is reduced.

FIG. 5 shows an alternative embodiment of the vertical transistor 100 illustrated in FIG. 4. In the embodiment illustrated in FIG. 5, a modified edge region 18A of the islands 93 is realized. The edge region of the transistors or the edge region of the many transistor cells is arranged on the edge of the islands 93 and may require specific edge termination structures in vertical transistors in order to prevent an increase in the electrical field and thus a higher component load. Such edge termination structures may, for example, be so-called junction termination extension JTE implantations, implanted guard rings or field plates. In the embodiment illustrated in FIG. 5, such an edge termination structure 18A is arranged in the modified edge region. This can prevent a reduction of the breakdown voltage as a result of an increase in the field. Alternatively or additionally, edge regions of the transistor, within which mechanical stress is reduced, may be electrically inactivated by means of the edge termination structure 18A. For example, edge termination structure 18A may at least partially extend into the region in which the masking layer 71 is laterally overgrown. In the laterally overgrown region, no direct vertical current flow takes place irrespective of the edge termination structure 18A.

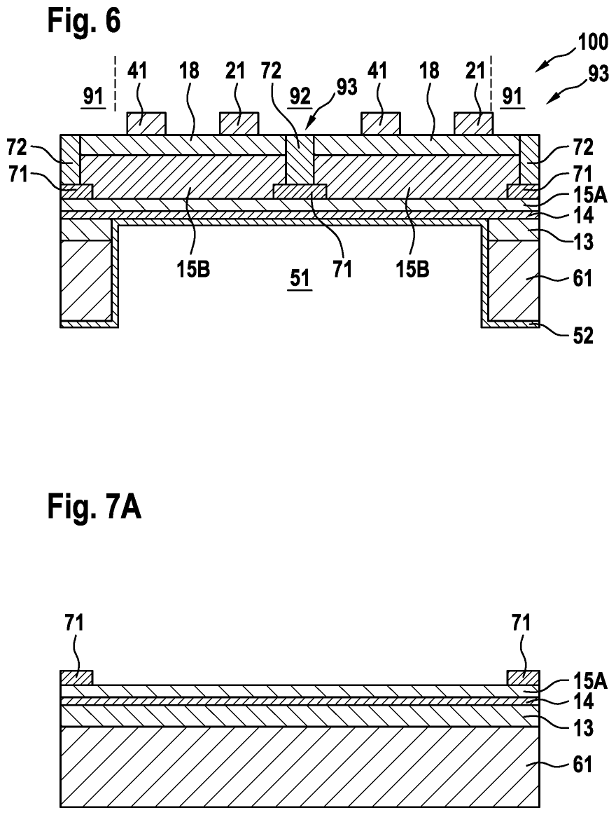

FIG. 6 shows an alternative embodiment of the vertical transistor 100 illustrated in FIG. 4. In the embodiment illustrated in FIG. 6, the region between the islands 93 is filled with a filler material 72. This filler material 72 can, for example, be a dielectric, e.g., SiO₂, SiN or phosphorus-doped silicate glass. Such a filling or forming of the filler material 72 can be achieved, after the epitaxial island growth, by means of common micromanufacturing methods, e.g., by means of conformal material deposition, e.g., by means of low-pressure chemical vapor deposition (LPCVD), plasma-enhanced chemical vapor deposition (PECVD), sputtering or spin-coating and a subsequent planarization to the height of the upper side of the component-defining layer system 18, for example by means of chemical-mechanical polishing (CMP) or recess dry-etching.

The embodiment illustrated in FIG. 6 may also be combined with the embodiment illustrated in FIG. 5. As a result, a planar surface for component processing can be realized, which can result in advantages, for example for a lithography process, for example a more even spin-coating of photoresists. In the vertical transistor 100, the connection of the islands 93 through the filler material 72 can lead to improved mechanical stability of the vertical transistor 100.

In various embodiments, the filler material 72 can be formed as a polycrystalline GaN layer. By appropriate choice of the masking layer 71 and of the growth conditions in an epitaxy process, the growth of a GaN layer 72 as a polycrystalline layer can be induced in parallel or simultaneously with the growth of the crystalline GaN layer 15B. Grain boundaries in a polycrystalline GaN filler material 72 can reduce stresses in the adjacent layers 15B, 18. As an alternative to a polycrystalline GaN filler material 72, a GaN filler material 72 having a high defect concentration can develop the same effect in the adjacent layers 15B, 18.

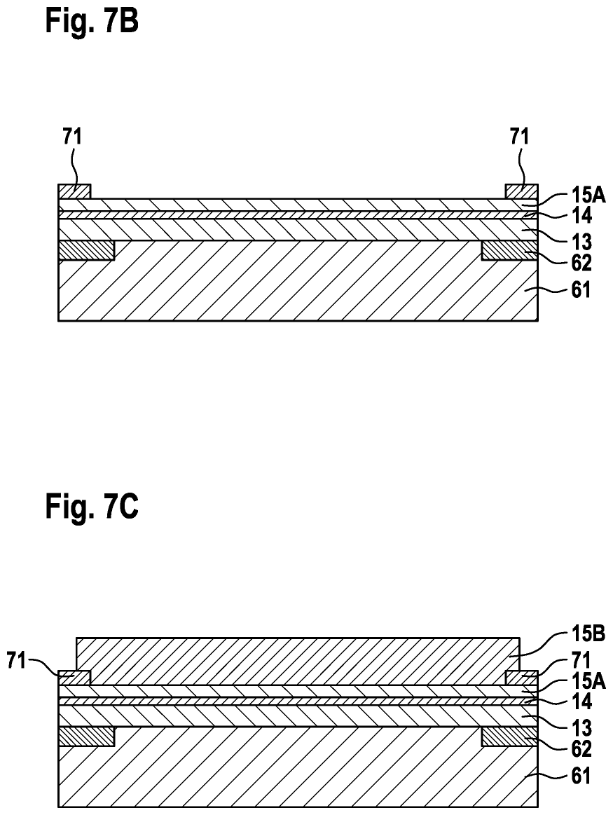

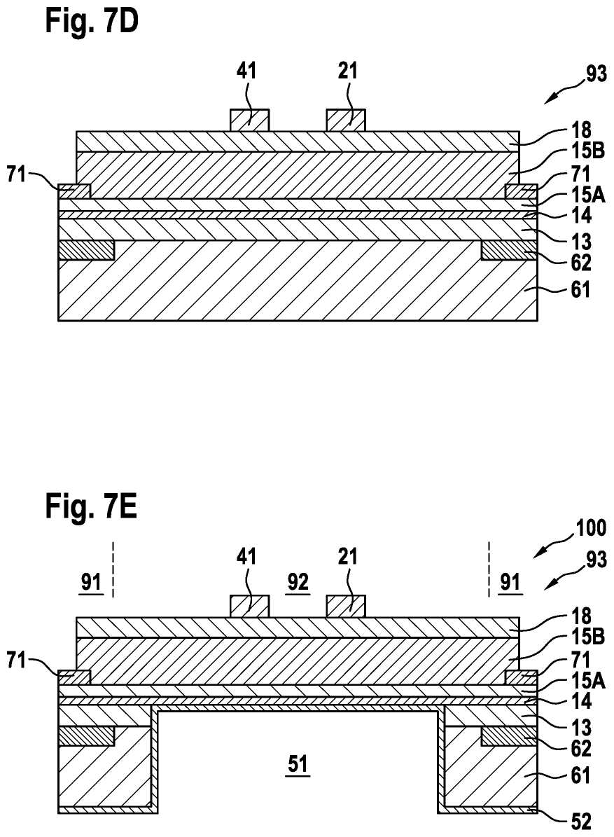

FIG. 7A to FIG. 7E illustrate, in schematic cross-sectional views, a production method of a vertical transistor 100 according to various embodiments. The embodiments illustrated in FIG. 4 to FIG. 6 with two or more islands 93 per common recess 51 may be combined analogously with the embodiment illustrated in FIG. 7A to FIG. 7E.

It is described in the related art that crystalline GaN growth can lead to a high mechanical load on an underlying silicon substrate 61. This can cause crystal damages in the silicon, which can negatively affect the yield.

In the embodiment illustrated in FIG. 7A to FIG. 7E, in contrast to the embodiment illustrated in FIG. 2A to FIG. 2E, after structuring the masking layer 71 by means of an isotropic etching step, a portion of the silicon substrate 61 under the edge of the masking layer 71 is therefore removed so that a removed region 62 is formed. Such etching may be carried out, for example, dry-chemically by means of XeF2, and thus, for example, selectively to III-V semiconductors and SiO₂, or may alternatively be carried out wet-chemically. As a result, mechanical stress can be reduced by a slight rotation of the free-standing GaN. A high load on the silicon substrate 61 can thereby be eliminated.

In various embodiments described above, an edge termination 18A illustrated in FIG. 5 can, for example, be formed within the lateral extension of the removed region 62.

The embodiments described and shown in the figures are selected by way of example only. Different embodiments may be combined with one another in whole or with respect to individual features. One embodiment may also be supplemented by features of another embodiment. The method steps described may furthermore be repeated and performed in a different order than that described. In particular, the present invention is not limited to the method specified.

1-15. (canceled)

16. A vertical transistor, comprising:
an outer region and a membrane region, wherein at least a portion of a semiconductor substrate is arranged in the outer region, wherein the semiconductor substrate is structured in such a way that a rear trench is arranged in the membrane region, wherein the rear trench is free of semiconductor substrate;
a masking layer in the outer region and/or in the membrane region; and
a layer stack in the membrane region, wherein the layer stack includes at least one drift layer, at least one component-defining layer system, and at least one control terminal;
wherein the masking layer is configured such that a region on the masking layer is substantially free of the layer stack so that a lateral extension of the layer stack is adjusted using the masking layer.

17. The vertical transistor according to claim 16, wherein the control electrode is a gate electrode.

18. The vertical transistor according to claim 16, further comprising:
a drain layer arranged in the outer region and the membrane region, wherein the drift layer, the component-defining layer system, and the control terminal are arranged at least in the membrane region on or above the drain layer.

19. The vertical transistor according to claim 18, further comprising:
an adaptation layer arranged at least in the outer region between the semiconductor substrate and the drain layer.

20. The vertical transistor according to claim 18, wherein the semiconductor substrate is structured in the outer region in such a way that a removed region is arranged between the semiconductor substrate and the adaptation layer and/or the masking layer.

21. The vertical transistor according to claim 16, further comprising:
a terminal contact arranged in the rear trench and electrically coupled to the component-defining layer system by the drift layer.

22. The vertical transistor according to claim 16, wherein the masking layer is arranged directly on the semiconductor substrate.

23. The vertical transistor according to claim 16, wherein the layer stack includes a multitude of control terminals arranged in the membrane region above a common rear trench.

24. The vertical transistor according to claim 16, wherein the layer stack is a first layer stack, and wherein a second layer stack, which includes the at least one drift layer, at least one component-defining layer system, and at least one control terminal, and the first layer stack are arranged in the membrane region above a common rear trench, wherein the first layer stack is laterally separated from the second layer stack.

25. The vertical transistor according to claim 24, wherein the gate electrode of the second layer stack includes a gate electrode.

26. The vertical transistor according to claim 24, wherein the masking layer is arranged in the membrane region, and the second layer stack is separated from the first layer stack using the masking layer in the membrane region.

27. The vertical transistor according to claim 16, wherein the layer stack further includes an edge termination structure arranged at least one lateral boundary of the layer stack, wherein the edge termination structure is configured to be electrically inactive.

28. The vertical transistor according to claim 27, wherein the edge termination structure is arranged at least partially above the masking layer.

29. The vertical transistor according to claim 16, further including a filler material on or above the masking layer, wherein the filler material at least partially contacts the layer stack laterally.

30. The vertical transistor according to claim 29, wherein the filler material includes or is formed from a polycrystalline material.

31. The vertical transistor according to claim 16, wherein the semiconductor substrate includes or is formed from silicon and the component-defining layer system includes or is formed from gallium nitride.

32. A method for producing a vertical transistor with an outer region and a membrane region, the method comprising:
structuring a semiconductor substrate in such a way that at least a portion of the semiconductor substrate is arranged in the outer region, and that a rear trench is arranged in the membrane region, wherein the rear trench is free of semiconductor substrate;
forming a masking layer in the outer region and/or in the membrane region; and
forming a layer stack in the membrane region, wherein the layer stack includes at least one drift layer, at least one component-defining layer system and at least one control terminal;
wherein the masking layer is configured such that a region on the masking layer remains substantially free of the layer stack so that a lateral extension of the layer stack is adjusted using the masking layer.

33. The method according to claim 32, wherein the control terminal is a gate terminal.
